(19) United States
(12) Patent Application Publication
(10) Pub. No.: US 2003/0052417 A1
(43) Pub. Date: Mar. 20, 2003

(54) Semiconductor device

(76) Inventor: Takashi Hosaka, Chiba-shi (JP)

Correspondence Address: ADAMS & WILKS, 31st Floor, 50 Broadway, New York, NY, 10004, US

(21) Appl. No.: 09/941,127

(22) Filed: Aug. 28, 2001

(51) Int. Cl. H01L 23/52

(52) U.S. Cl. 257/786

(57) ABSTRACT

To minimize the area of a chip-size package provided with balls, an equilateral triangle defined by pitches between balls is used as a basic shape, and a chip is formed into a shape in which the equilateral triangles are arranged side by side.

### BACKGROUND OF THE INVENTION

1. Field of the Invention

The present invention relates to a shape of a so-called chip-size package (CSP) with the same size as that of an IC chip that is formed of a wafer level CSP or the like.

2. Description of the Related Art

General semiconductor chips ever made including a wafer level CSP had a rectangular shape as shown in FIG. 5.

In the case of the water level CSP, balls must be formed in a region of a semiconductor chip. For example, as shown in FIG. 5, balls are not arranged to have a shortest ball pitch between each two of them. Hence, the semiconductor chip is not allowed to have a minimum size. In other words, in FIG. 5, since the semiconductor chip 51 has a rectangular shape, when the distance between a ball 52 and adjacent balls 53 and 55 which serve as leads, is set to a shortest ball pitch, the distance between the ball 52 and an opposing a facing ball 54 cannot be set to the shortest pitch.

### SUMMARY OF THE INVENTION

In order to solve the above-mentioned problem, according to the present invention, a semiconductor chip is formed into an equilateral triangular shape or into a shape similar to an equilateral triangular shape. Alternatively, a semiconductor chip is formed into an equilateral triangular shape or into a shape in which equilateral triangles are arranged side by side.

### BRIEF DESCRIPTION OF THE DRAWINGS

In the accompanying drawings:

FIG. 1 shows a semiconductor chip with three pins having an equilateral triangular shape in accordance with the present invention;

FIG. 2 shows a semiconductor chip with four pins having a rhombic shape in accordance with the present invention;

FIG. 3 shows a semiconductor chip with five pins having a trapezoidal shape in accordance with the present invention;

FIGS. 4A and 4B show semiconductor chips with six pins in accordance with the preset invention; and

FIG. 5 shows a conventional semiconductor chip having a rectangular shape.

### DETAILED DESCRIPTION OF THE PREFERRED EMBODIMENTS

The present invention allows the size of a chip-size package such as one called a wafer level CSP to be minimized. In the wafer level CSP, balls corresponding to leads of the package are provided. Since a plurality of balls are provided, there exists a shortest distance between these balls. Further, with respect to the size of the balls, a minimum size is fixed, and thus there gives a minimum ball pitch determined by the shortest distance and the minimum size.

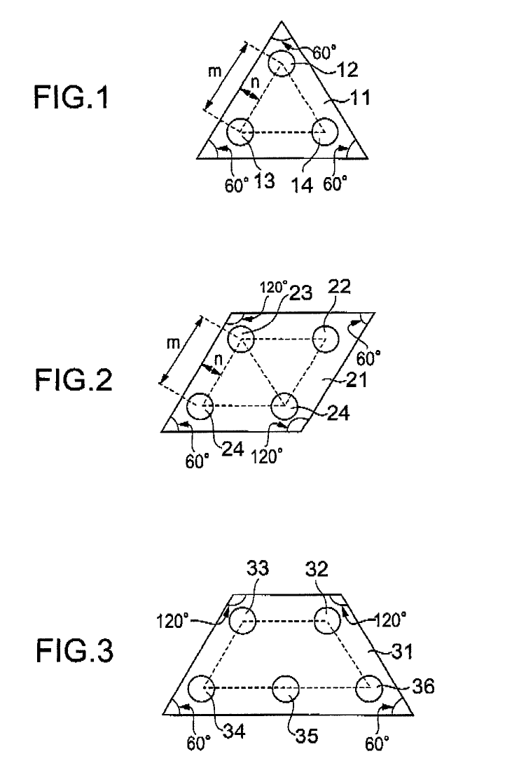

FIG. 1 is a semiconductor chip 11 with three pins, three pieces, of balls. FIG. 1 shows a semiconductor chip seen from its side with the balls, its back side. The minimum ball pitch is indicated with m. Since three pins are used, a minimum area defined by the three pins of balls is obtained when the balls define an equilateral triangular shape with a distance m put between each two of the balls. When the shortest distance from a peripheral side of the chip to the center of a ball is indicated with n, the chip has a minimum area when having a shape of an equilateral triangle with a side of m+2×3^{½}×n. Conversely, when a chip having a shape of an equilateral triangle with a side of m+2×3^{½}×n is produced, a smallest chip-size package (CPS) can be obtained.

Next, the description will be given of the case of four pins with reference to FIG. 2. A chip may be formed into a shape in which two equilateral triangles with three pins are arranged side by side, i.e. into a rhombic shape. In this case, a chip is obtained that has a shape of a rhomb with a side of m+2×3^{½}×n. In the case of five pins, as shown in FIG. 3, a chip may be formed into a shape of a trapezoid with three sides of m+2×3^{½}×n and the other one side of 2*(m+2×3^{½}×n).

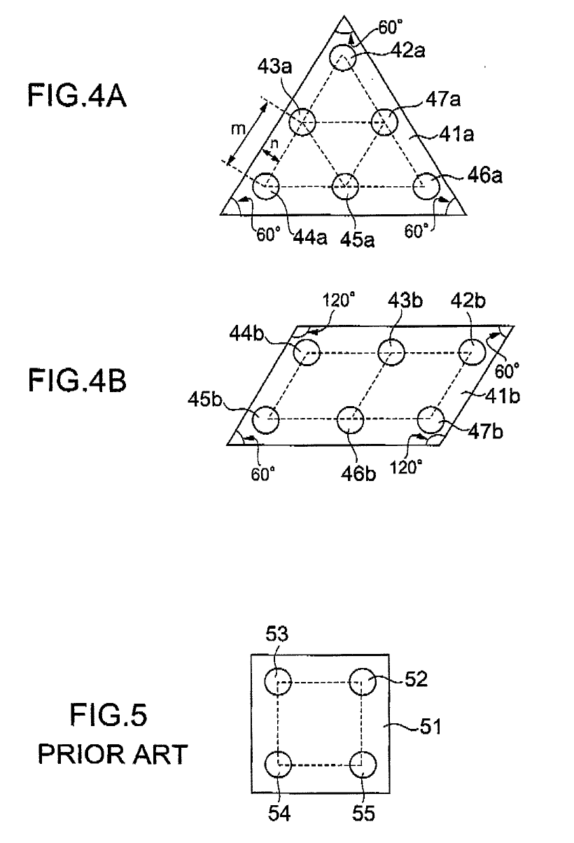

In the case of six pins, as shown in FIG. 4(A), a semiconductor chip 41a has a shape of an equilateral triangle with a side of 2m+2×3^{½}×n, wherein m denotes a distance between adjacent balls and n indicates a distance from a peripheral side to the center of each of the electrode balls 42a, 45a, 44a, 43a, and 46a. Further, as shown in FIG. 4B, electrode balls 42b, 43b, 44b, 45b, 46b, and 47b may be arranged on a semiconductor chip 41b having a shape of a parallelogram with two sides of m+2×3^{½}×n and the other two sides of 2m+2×3^{½}×n. In the case of n pins, a required number of equilateral triangles with a minimum shape may be arranged.

As described above, when equilateral triangles defined by balls disposed at a minimum ball pitch are arranged side by side, a CSP with a minimum chip size can be formed, and thus a most inexpensive CSP is obtained.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A semiconductor device, comprising a semiconductor chip having a shape in which one of an equilateral triangle and a shape similar to the equilateral triangle is used as a basic shape, and a required number of one of the equilateral triangles and the shapes similar to the equilateral triangle are arranged side by side.

2. A semiconductor device, comprising a semiconductor chip having a shape in which one of equilateral triangles and shapes similar to the equilateral triangle are arranged side by side.

3. A semiconductor device, comprising a semiconductor chip having one of a rhombic shape and a shape similar to the rhombic shape.

4. A semiconductor device, comprising a semiconductor chip having one of a trapezoidal shape and a shape similar to the trapezoidal shape.

5. A semiconductor device according to claim 1;
wherein electrode balls corresponding to leads of an IC chip are mounted on one side or on both sides of a semiconductor chip.
